(19) United States
(12) Patent Application Publication
(10) Pub. No.: US 2009/0105976 A1
(43) Pub. Date: Apr. 23, 2009

(54) AUTOMATIC JITTER MEASUREMENT METHOD

(75) Inventor: Shang-Yi Wang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/254,806

(22) Filed: Oct. 20, 2008

(30) Foreign Application Priority Data
Oct. 23, 2007 (TW) 96139695

(51) Int. Cl. G01R 13/00

(52) U.S. Cl. 702/67; 702/69

(57) ABSTRACT

An automatic jitter measurement method for an oscilloscope is provided. The method includes: establishing a database in a data processing unit, in which the step of establishing the database includes establishing at least a horizontal delay parameter and a horizontal scale parameter; enabling the oscilloscope for fetching a test signal, according to the horizontal delay parameter and the horizontal scale parameter; enabling a signal accumulation function of the oscilloscope for obtaining a signal accumulation maximum position value and a signal accumulation minimum position value of the test signal; and adjusting a display position of the test signal on the oscilloscope to obtain a jitter value of the test signal according to the signal accumulation maximum position value and the signal accumulation minimum position value.

### CROSS-REFERENCE TO RELATED APPLICATION

This application claims the priority benefit of Taiwan application serial no. 96139695, filed on Oct. 23, 2007. The entirety of the above-mentioned patent application is hereby incorporated by reference herein and made a part of specification.

### BACKGROUND OF THE INVENTION 1. Field of the Invention

The present invention generally relates to a jitter measurement method for an oscilloscope, and more particularly, to a jitter measurement method for a digital oscilloscope, adapted for automatically adjusting a signal display position of the digital oscilloscope.

2. Description of Related Art

When using an oscilloscope, e.g., a digital oscilloscope, in measuring signals, it is often desired to display a test signal at a central position of a screen of the oscilloscope, for allowing the operator conveniently viewing and measuring a jitter amount of the test signal, or recording images thereof.

However, presently, the only way to adjust the test signal to display at the desired central position of the screen of the oscilloscope is manually adjusting a horizontal delay parameter and a horizontal position parameter of the oscilloscope by turning corresponding knobs, and a jitter amount of the test signal can be manually measured only.

### SUMMARY OF THE INVENTION

Accordingly, the present invention is directed to provide a jitter measurement method for an oscilloscope. The jitter measurement method is adapted for automatically setting parameters of the oscilloscope, instead of manually setting the parameters of the oscilloscope by the operator.

The present invention is further directed to provide a jitter measurement method for an oscilloscope, which is adapted for automatically adjusting a signal display position, instead of manually adjusting the signal display position by the operator.

The present invention is further directed to provide a jitter measurement method for an oscilloscope, which is adapted for automatically determining a jitter amount of a signal, instead of manually determining the jitter amount of the signal by the operator.

According to an embodiment of the present invention, an automatic jitter measurement method for measuring a test signal of an oscilloscope is provided. The method includes: establishing a database in a data processing unit, in which the step of establishing the database includes establishing at least a horizontal delay parameter and a horizontal scale parameter; enabling the oscilloscope for fetching the test signal according to the horizontal delay parameter and the horizontal scale parameter; enabling a signal accumulation function of the oscilloscope for obtaining a signal accumulation maximum position value and a signal accumulation minimum position value of the test signal; and adjusting a display position of the test signal on the oscilloscope to obtain a jitter value of the test signal according to the signal accumulation maximum position value and the signal accumulation minimum position value.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a measurement system according to an embodiment of the present invention.

FIG. 2 is a flow chart illustrating a flow of automatically adjusting a display position and automatically measuring a jitter value according to an embodiment of the present invention.

FIG. 3A illustrates a waveform of a test signal IN fetched by an oscilloscope 102.

FIG. 3B is an enlarged view of a position A of a certain segment of the test signal IN.

FIG. 3C schematically illustrates a signal accumulation maximum position value MAX, and a signal accumulation minimum position value MIN of the test signal, and a central position BC.

FIG. 4A shows a result of enabling a signal accumulation function.

FIG. 4B is an enlarged view of FIG. 4A.

FIG. 4C illustrates the result of adjusting the test signal IN to the central position.

FIG. 5 illustrates a jitter measurement method for automatically measuring the test signal IN with an oscilloscope according to a further embodiment of the present invention.

### DESCRIPTION OF THE EMBODIMENTS

Reference will now be made in detail to the present preferred embodiments of the invention, examples of which are illustrated in the accompanying drawings. Wherever possible, the same reference counting numbers are used in the drawings and the description to refer to the same or like parts.

Generally, different operators may obtain different results from respective manual adjustments. Therefore, it is desired to develop a jitter measurement method for an oscilloscope, which can automatically maintain a test signal at a central position of a screen of the oscilloscope, so as to allow the operator conveniently viewing or recording an image thereof.

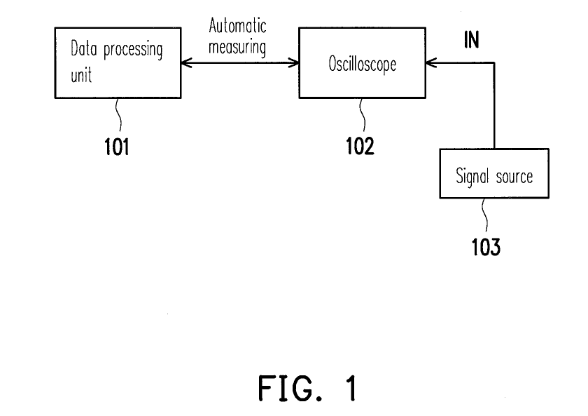

FIG. 1 illustrates a measurement system according to an embodiment of the present invention. As shown in FIG. 1, a data processing unit 101 is configured with at least a network connection function and a data processing function. The data processing unit 101 is, for example, a personal computer (PC), or a notebook computer (NB). The data processing unit 101 can obtain an output result and data of an oscilloscope 102, control the oscilloscope 102, and transmit calculation/operation results to the oscilloscope 102, in accordance with the network connection function. The oscilloscope 102 for example is a digital oscilloscope. A signal source 103 provides a test signal IN for the oscilloscope 102. For example, when measuring a jitter value of an electrical signal of a 1394 interface of a mainboard according to the current embodiment, the signal source 103 is a test mainboard having a 1394 interface, while the test signal IN is a 1394 signal. Of course, those skilled in the art should understand that the present invention can be applied for measuring other signals, such as a USB interface signal, or a clock signal of an electrical system.

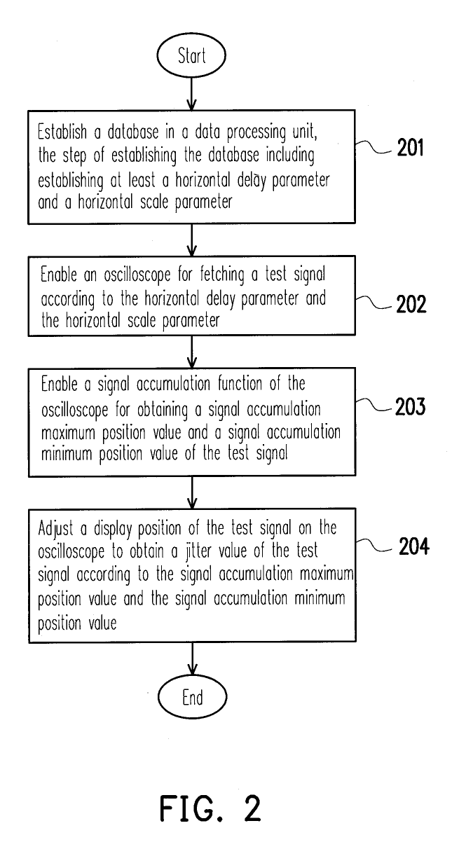

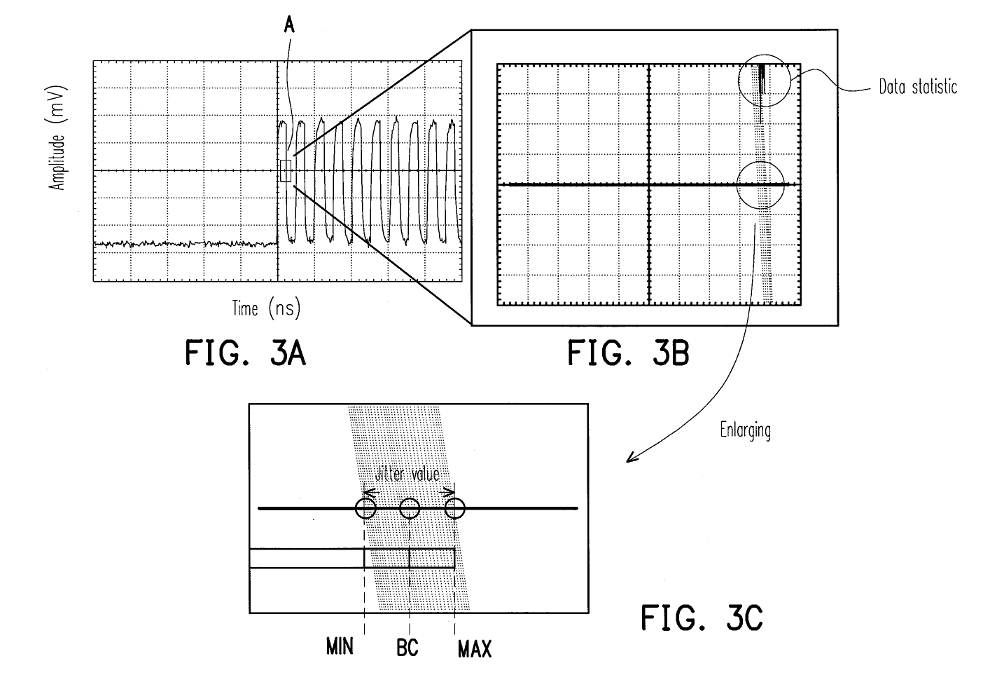

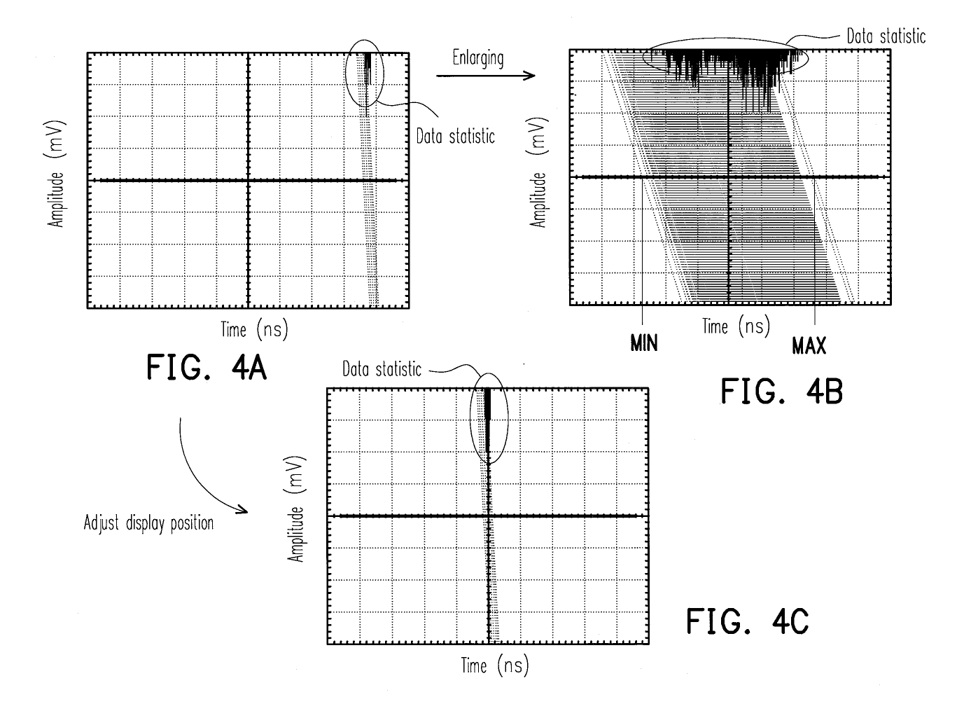

FIG. 2 is a flow chart illustrating a flow of automatically adjusting a display position and automatically measuring a jitter value according to an embodiment of the present invention. FIG. 3A illustrates a waveform of a test signal IN fetched by an oscilloscope 102. FIG. 3B is an enlarged view of a position A of a certain segment of the test signal IN. FIG. 3C schematically illustrates a signal accumulation maximum position value MAX, and a signal accumulation minimum position value MIN of the test signal, and a central position BC. FIG. 4A shows a result of enabling a signal accumulation function. FIG. 4B is an enlarged view of FIG. 4A. FIG. 4C illustrates the result of adjusting the test signal IN to the central position.

FIGS. 2 through 4C are to be discussed herebelow.

As shown in FIG. 2, at step 201, an operator establishes a database in the data processing unit 101, in which the step of establishing the database includes establishing at least a horizontal delay parameter and a horizontal scale parameter. In other words, the database at least includes a horizontal delay parameter and a horizontal scale parameter. A table is given as below for exemplifying the database.

| | horizontal delay parameter | horizontal scale parameter |
|---|---|---|
| A(100) | 1E−8 | 5E−11 |
| A(200) | 5E−9 | 5E−11 |
| A(400) | 2.5E−9 | 5E−11 |
| B(100) | 1E−8 | 5E−11 |
| B(200) | 5E−9 | 5E−11 |
| B(400) | 2.5E−9 | 5E−11 |
| C(100) | 1E−8 | 5E−11 |
| C(200) | 5E−9 | 5E−11 |
| C(400) | 2.5E−9 | 5E−11 |
| D(100) | 1E−8 | 1E−10 |
| D(200) | 5E−9 | 1E−10 |
| D(400) | 2.5E−9 | 1E−10 |

In the above recited table, A through D represents different 1394 chip suppliers, in which A(100) represents a certain specification provided by supplier A, and other symbols are defined in a similar way.

Then, at step 202, the oscilloscope 102 is enabled according to the established horizontal delay parameter and horizontal scale parameter for fetching the test signal IN. In such a way, the oscilloscope 102 fetches repetitively transmitted test signal IN from the signal source 103. In this case, the test signal IN is considered as unideal. The test signal IN may be caused unideal because of mainboard layout factor, or inrush current. However, whatever the reason of causing the unideal test signal is, it should be attributed to interference to the signal. Since the test signal IN is an unideal signal, the test signal IN will distribute on the oscilloscope 102 within in a specific range, i.e., the test signal IN presents different waveforms, and the specific range is configured by overlapping the different waveforms. An ideal signal will displays a signal waveform on the oscilloscope 102. When the operator sets the chip supplier of the mainboard via a human-machine interface (not shown in the drawings) of the data processing unit 101, the oscilloscope 102 can then find out a general position A of a certain signal segment of the test signal IN through the established database, e.g., a first falling edge of the test signal IN (referring to FIG. 3A). Further, for measurement convenience, the general position A is enlarged as shown in FIG. 3B.

Then, at step 203, a signal accumulation function of the oscilloscope 102 is enabled for obtaining a signal accumulation maximum position value MAX and a signal accumulation minimum position value MIN of the test signal IN. Hence, the signal accumulation function of the oscilloscope 102 is automatically enabled by the data processing unit 101, while according to the conventional technology the signal accumulation function should be manually enabled by the operator. The signal accumulation function includes: signal stacking function (the stacked test signal is as shown in FIGS. 3A and 3B); and data histogram box function.

The data histogram box function is subject to count the time points and times of the test signal IN passing a reference axis, e.g., a voltage amplitude 0V, as shown in FIG. 3B and upper sections of FIGS. 4A through 4C. FIG. 4B illustrates the signal accumulation maximum position value MAX and the signal accumulation minimum position value MIN of the test signal IN, for the convenience of understanding the definitions thereof.

Then, at step 204, a display position of the test signal on the oscilloscope 102 is adjusted to obtain a jitter value of the test signal IN, according to the signal accumulation maximum position value MAX and the signal accumulation minimum position value MIN of the test signal IN.

Then, a new display position of the test signal is counted according to the signal accumulation maximum position value MAX and the signal accumulation minimum position value MIN of the test signal IN. The oscilloscope 102 transmits the signal accumulation maximum position value MAX and the signal accumulation minimum position value MIN of the test signal IN to the data processing unit 101. The data processing unit 101 then calculates a bandwidth center point BC of the test signal IN. Then, the oscilloscope 102 can obtain the new display position of the test signal IN on the oscilloscope 102 according to the bandwidth center point BC calculated by the data processing unit 101. The oscilloscope 102 then automatically adjusts and displays the test signal IN on the oscilloscope 102 according to the new display position.

In the current embodiment, suppose BC=(MAX+MIN)/2, as shown in FIG. 3C. The BC value represents a central position of an accumulation signal of the test signal IN on the timing axis. The operation of calculating the BC value is conducted by the data processing unit 101. The data processing unit 101 transmits the obtained BC value to the oscilloscope 102, and sets the BC value as the horizontal delay parameter of the oscilloscope 102. In such a way, the display position of the test signal IN is moved to a central position of the screen of the oscilloscope 102, as shown in FIG. 4C.

It should be noted that because signals of the mainboard usually more or less have variation, while the test signal can be generally found out according to positional parameters in the database, e.g., horizontal delay parameter and horizontal scale parameter, therefore the display position of the test signal IN is desired to be adjusted to the center of the screen of the oscilloscope 102, for allowing conveniently viewing and measuring.

In the current embodiment, the jitter value of the test signal IN is equal to the difference between the signal accumulation maximum position value MAX and the signal accumulation minimum position value MIN of the test signal IN (i.e., jitter value=MAX−MIN). This calculation operation is conducted by the data processing unit 101.

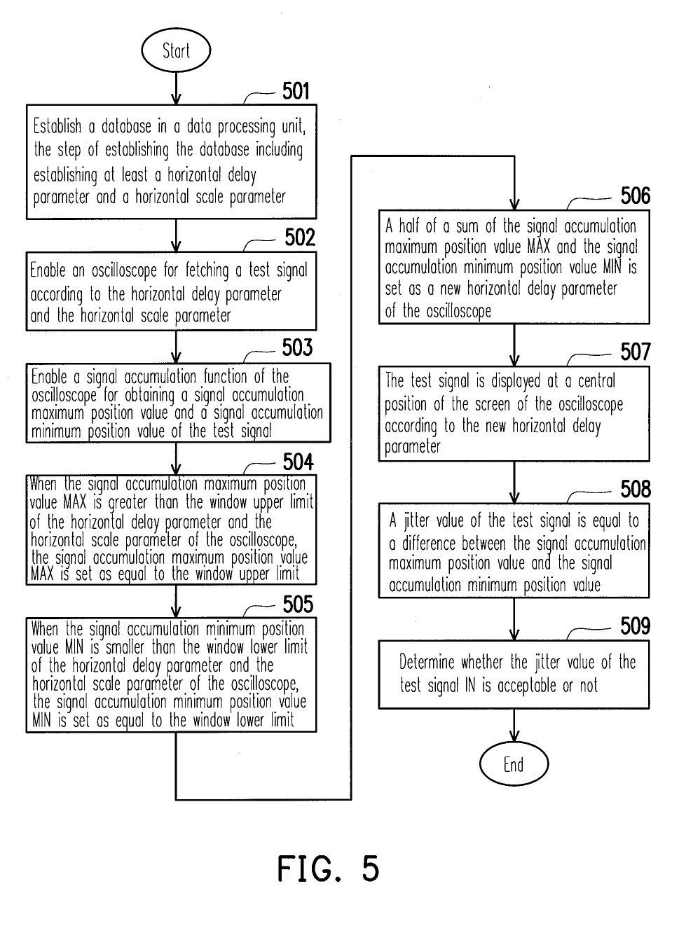

FIG. 5 illustrates a jitter measurement method for automatically measuring the test signal IN with an oscilloscope according to a further embodiment of the present invention. Referring to FIG. 5, steps 501 through 503 can be same or similar as the steps 201 through 203 of FIG. 2, and the details thereof are not to be iterated hereby.

However, the signal accumulation maximum position value MAX and the signal accumulation minimum position value MIN of the test signal IN obtained at step 503 may sometimes exceed window upper/lower limits of the horizontal delay parameter and the horizontal scale parameter of the oscilloscope 102. Therefore, in this case, how to correctly set the signal accumulation maximum position value MAX and the signal accumulation minimum position value MIN should be considered.

At step 504, when the signal accumulation maximum position value MAX is greater than the window upper limit of the horizontal delay parameter and the horizontal scale parameter of the oscilloscope 102, the signal accumulation maximum position value MAX is set as equal to the window upper limit.

At step 505, when the signal accumulation minimum position value MIN is smaller than the window lower limit of the horizontal delay parameter and the horizontal scale parameter of the oscilloscope 102, the signal accumulation minimum position value MIN is set as equal to the window lower limit.

In the current embodiment, the display position of the test signal IN is also to be adjusted. For example, the display position of the test signal IN can be adjusted to the central position BC. Detail procedures are as shown in steps 506 and 507.

As shown in step 506, a half of a sum of the signal accumulation maximum position value MAX and the signal accumulation minimum position value MIN is set as a new horizontal delay parameter of the oscilloscope 102.

As shown in step 507, the test signal IN is displayed at a central position of the screen of the oscilloscope 102 according to the new horizontal delay parameter.

As shown in step 508, a jitter value of the test signal is equal to a difference between the signal accumulation maximum position value MAX and the signal accumulation minimum position value MIN.

As shown in step 509, the data processing unit 101 can also determine whether the test signal IN is acceptable or not, i.e., determining whether the jitter value of the test signal IN is acceptable or not. For example, the measurement result, the screen images of the oscilloscope 102 and the measurement data are transmitted to the data processing unit 101 and stored there. Then, the data processing unit 101 determines the measurement data to be Pass or Fail, according to the 1394 specification, and displays the determined result on a user interface of the data processing unit 101.

In accordance with the foregoing embodiment of the present invention, the operator is allowed for automatically adjusting the display position of the test signal IN on the oscilloscope 102 by the data processing unit 101, and automatically calculating a jitter value of the test signal IN, so as to automatically determine whether the test signal IN is acceptable or not.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An automatic jitter measurement method, comprising:
establishing a database in a data processing unit, wherein the step of establishing the database comprises establishing at least a horizontal delay parameter and a horizontal scale parameter;
enabling an oscilloscope for fetching a test signal, according to the horizontal delay parameter and the horizontal scale parameter;
enabling a signal accumulation function of the oscilloscope, for obtaining a signal accumulation maximum position value and a signal accumulation minimum position value of the test signal; and
adjusting a display position of the test signal on the oscilloscope to obtain a jitter value of the test signal, according to the signal accumulation maximum position value and the signal accumulation minimum position value.

2. The automatic jitter measurement method according to claim 1, wherein the data processing unit comprises a personal computer or a notebook computer having a network connection function.

3. The automatic jitter measurement method according to claim 1, wherein in the step of enabling the signal accumulation function of the oscilloscope for obtaining the signal accumulation maximum position value and the signal accumulation minimum position value of the test signal, when the signal accumulation maximum position value is greater than a window upper limit of the horizontal delay parameter and the horizontal scale parameter of the oscilloscope, the signal accumulation maximum position value is set as equal to the window upper limit of the horizontal delay parameter and the horizontal scale parameter of the oscilloscope.

4. The automatic jitter measurement method according to claim 1, wherein in the step of enabling the signal accumulation function of the oscilloscope for obtaining the signal accumulation maximum position value and the signal accumulation minimum position value of the test signal, when the signal accumulation minimum position value is smaller than a window lower limit of the horizontal delay parameter and the horizontal scale parameter of the oscilloscope, the signal accumulation minimum position value is set as equal to the window lower limit of the horizontal delay parameter and the horizontal scale parameter of the oscilloscope.

5. The automatic jitter measurement method according to claim 1, wherein the jitter value of the test signal is equal to a difference between the signal accumulation maximum position value and the signal accumulation minimum position value.

6. The automatic jitter measurement method according to claim 1, wherein in the step of adjusting the display position of the test signal on the oscilloscope to obtain the jitter value of the test signal, the test signal is adjusted to a half of a sum of the signal accumulation maximum position value and the signal accumulation minimum position value.

7. The automatic jitter measurement method according to claim 1, wherein a half of a sum of the signal accumulation maximum position value and the signal accumulation minimum position value is used for setting a new horizontal delay parameter of the oscilloscope.

8. The automatic jitter measurement method according to claim 7, wherein the test signal is displayed at a central position of a screen of the oscilloscope, according to the new horizontal delay parameter.

9. The automatic jitter measurement method according to claim 1, wherein the step of enabling the signal accumulation function of the oscilloscope comprising:
enabling a signal stacking function of the oscilloscope; and
enabling a data histogram box function of the oscilloscope.

10. The automatic jitter measurement method according to claim 5, further comprising:
determining whether the jitter value of the test signal is acceptable or not.
